(19) United States
(12) Patent Application Publication
(10) Pub. No.: US 2010/0209217 A1
(43) Pub. Date: Aug. 19, 2010

(54) WORK TRANSFER APPARATUS

(75) Inventors: Kunio Fukuma, Osaka (JP); Hideki Matsuo, Osaka (JP); Daisuke Sado, Osaka (JP)

Correspondence Address: HAMRE, SCHUMANN, MUELLER & LARSON, P.C., P.O. BOX 2902, MINNEAPOLIS, MN, 55402-0902, US

(73) Assignee: DAIHEN CORPORATION, Osaka (JP)

(21) Appl. No.: 12/633,298

(22) Filed: Dec. 8, 2009

(30) Foreign Application Priority Data
Dec. 8, 2008 (JP) 2008-311705
Jul. 31, 2009 (JP) 2009-179339

(51) Int. Cl. H01L 21/677

(52) U.S. Cl. 414/217

(57) ABSTRACT

A work transfer apparatus includes a hand mechanism, a scissors lift mechanism, a seat, and a rotary mechanism. The hand mechanism supports and reciprocates a work. The scissors lift mechanism supports the hand mechanism, and moves the hand mechanism vertically, i.e., raises or lowers it. The seat supports the scissors lift mechanism. The rotary mechanism rotates the seat around a vertical axis. The scissors lift mechanism includes a stage on which the hand mechanism is mounted, at least one scissors link, and a lift driver.

### BACKGROUND OF THE INVENTION

1. Field of the Invention

The present invention relates to a work transfer apparatus for transferring a plate-shaped work in e.g. a vacuum space.

2. Background of the Art

An example of work transfer apparatus for transferring a plate-shaped work in a vacuum space is disclosed in JP-A-2007-118171. The work transfer apparatus disclosed in the document includes a stationary base, a rotary base rotatably supported by the stationary base, an elevation base supporting the rotary base, a ball screw slide mechanism for moving the elevation base supporting the rotary base in a vertical direction, a link arm mechanism supported by the rotary base, and a hand supported by the link arm mechanism.

The hand and the link arm mechanism are arranged in a vacuum space, whereas most part of the housing of the stationary base is arranged in an atmospheric space below the vacuum space. The stationary base accommodates a motor for rotating the rotary base and driving the link arm mechanism, the ball screw slide mechanism and a driving motor for the ball screw slide mechanism.

In the conventional work transfer apparatus, various kinds of driving motors are accommodated in the stationary base. Accordingly, the stationary base and hence, the transfer apparatus as a whole tend to be rather large.

### SUMMARY OF THE INVENTION

The present invention has been proposed under the circumstances described above. It is therefore an object of the present invention to provide a work transfer apparatus which is suitable for reducing the overall size and, in particular, downsizing the vertical dimension.

According to a first aspect of the present invention, there is provided a work transfer apparatus that includes: a hand mechanism for reciprocally moving a work; a scissors lift mechanism for supporting the hand mechanism and moving the hand mechanism up and down in a vertical direction; a seat supporting the scissors lift mechanism; and a rotary mechanism for rotating the seat around a vertical axis.

According to a second aspect of the present invention, the hand mechanism includes a hand for holding the work, a slide link mechanism supporting the hand and linearly moving the hand reciprocally, and a slide driver for operating the slide link mechanism. The scissors lift mechanism includes a stage supporting the hand mechanism, at least one scissors link, and a lift driver. The scissors link includes a first and a second cross arms rotatably connected to each other at a crossing point, where the first cross arm includes an upper end that is slidable relative to the stage in a horizontal direction, while also including a lower end connected to the seat rotatably around a first horizontal axis. The second cross arm includes an upper end that is rotatable relative to the stage around a second horizontal axis, while also including a lower end connected to the seat slidably in a horizontal direction. The lift driver is mounted on the seat and configured to cause the lower end of the second cross arm to slide relative to the seat.

According to a third aspect of the present invention, the work transfer apparatus of the second aspect further includes a plurality of pipes arranged between the hand mechanism and the seat, where the pipes are communicably connected to each other and rotatable around a horizontal axis.

According to a fourth aspect of the present invention, the work transfer apparatus of the third aspect further includes a cable accommodated in the pipes and connected to the hand mechanism.

According to a fifth aspect of the present invention, the work transfer apparatus of the third aspect, the scissors link includes a first and a second scissors links provided on the seat in parallel to each other. The pipes include a lower pipe, an upper pipe, and a middle pipe arranged between the upper pipe and the lower pipe, where the upper pipe and the lower pipe are spaced from each other in a horizontal direction. The lower pipe extends from the lower end of the second cross arm of the first scissors link to the crossing point in the first scissors link, the upper pipe extends from the upper end of the second cross arm of the second scissors link to the crossing point in the second scissors link, and the middle pipe is disposed between the crossing points in the first scissors link and the second scissors link and communicably connected to the lower pipe and the upper pipe.

According to a six aspect of the present invention, the work transfer apparatus of the fifth aspect further includes a swivel joint rotatable around a third horizontal axis, where the swivel joint is connected to one of the lower pipe and the upper pipe and to the middle pipe.

According to a seventh aspect of the present invention, the work transfer apparatus of the sixth aspect further includes a through pipe provided at the seat, where the through pipe is arranged to communicate with the lower pipe via the lower end of the first cross arm of the first scissors link.

According to an eighth aspect of the present invention, the work transfer apparatus of the seventh aspect further includes first, second, third and fourth joints. The first joint and the second joint are provided at the lower end and the crossing point, respectively, of the first cross arm of the first scissors link, and the third joint and the fourth joint are provided at the crossing point and the upper end, respectively, of the second cross arm of the second scissors link. The lower end of the lower pipe is communicably connected to the through pipe directly or indirectly via the first joint, and the upper end of the lower pipe is communicably connected to the middle pipe via the second joint. The lower end of the upper pipe is communicably connected to the middle pipe via the third joint, and the upper end of the upper pipe is communicably connected to the hand mechanism directly or indirectly via the fourth joint.

According to a ninth aspect of the present invention, in the work transfer apparatus of the eighth aspect, at least one of the second joint and the third joint is a swivel joint rotatable around the third horizontal axis.

According to a tenth aspect of the present invention, the work transfer apparatus of the fifth aspect further includes a through pipe provided at the seat. The lower end of the lower pipe is communicably connected to the through pipe directly or indirectly via the lower end of the first cross arm of the first scissors link to be rotatable around the first horizontal axis, and the upper end of the lower pipe is communicably connected to the middle pipe via the crossing point of the first cross arm of the first scissors link to be rotatable around a third horizontal axis. The lower end of the upper pipe is communicably connected to the middle pipe via the crossing point of the second cross arm of the second scissors link to be rotatable around the third horizontal axis, and the upper end of the upper pipe is communicably connected to the hand mechanism directly or indirectly via the upper end of the second cross arm of the second scissors link to be rotatable around the second horizontal axis.

According to an eleventh aspect of the present invention, the work transfer apparatus of the tenth aspect further includes a cable connected to the hand mechanism and another cable connected to the lift driver, where these cables are accommodated in the through pipe.

According to a twelfth aspect of the present invention, in the work transfer apparatus of the fifth aspect, the lower pipe, the middle pipe and the upper pipe are hermetically sealed.

According to a thirteenth aspect of the present invention, in the work transfer apparatus of the fifth aspect, each of the lower pipe, the middle pipe and the upper pipe includes a portion using an elastic member.

According to a fourteenth aspect of the present invention, in the work transfer apparatus of the third aspect, the pipes include an upper pipe and a lower pipe. The lower pipe is connected directly or indirectly to the seat to be rotatable around the first horizontal axis, the upper pipe is connected directly or indirectly to the hand mechanism to be rotatable around the second horizontal axis, and the upper pipe and the lower pipe are communicably connected to each other directly or indirectly to be rotatable around a third horizontal axis.

According to a fifteenth aspect of the present invention, the work transfer apparatus of the fourteenth aspect further includes: a swivel joint rotatable around the first horizontal axis and provided at a connection portion of the lower pipe with respect to the seat; a swivel joint rotatable around the second horizontal axis and provided at a connection portion of the upper pipe with respect to the hand mechanism; and a swivel joint rotatable around the third horizontal axis and provided at a communicable connection portion between the lower pipe and the upper pipe.

According to a sixteenth aspect of the present invention, in the work transfer apparatus of the fifteenth aspect, the first horizontal axis, the second horizontal axis and the third horizontal axis extend in parallel to each other, and the third horizontal axis is constantly positioned on a same side of a straight line connecting the first horizontal axis and the second horizontal axis to each other when viewed in a direction in which the first, the second and the third horizontal axes extend.

According to a seventeenth aspect of the present invention, in the work transfer apparatus of the sixteenth aspect, a distance between the first horizontal axis and the third horizontal axis is equal to a distance between the second horizontal axis and the third horizontal axis, and the first horizontal axis and the second horizontal axis are spaced vertically from each other.

According to an eighteenth aspect of the present invention, in the work transfer apparatus of the seventeenth aspect, the upper pipe and the lower pipe are arranged to provide a bending form.

According to a nineteenth aspect of the present invention, the work transfer apparatus of the fourteenth aspect further includes a through pipe provided at the seat, where the lower pipe is communicably connected to the through pipe directly or indirectly to be rotatable around the first horizontal axis.

According to, a twentieth aspect of the present invention, the work transfer apparatus of the nineteenth aspect further includes a cable accommodated in the through pipe and connected to the hand mechanism.

Other features and advantages of the present invention will become more apparent from detailed description given below with reference to the accompanying drawings.

### BRIEF DESCRIPTION OF THE DRAWINGS

FIG. 1 is a perspective view illustrating a work transfer apparatus according to a first embodiment of the present invention;

FIG. 2 is a side view illustrating parts of the work transfer apparatus of FIG. 1;

FIG. 3 is a front view illustrating parts of the work transfer apparatus of FIG. 1;

FIG. 4 is a perspective view illustrating a work transfer apparatus according to a second embodiment of the present invention;

FIG. 5 is a front view illustrating parts of a work transfer apparatus according to a third embodiment of the present invention;

FIG. 6 is a perspective view illustrating an example of hand mechanism used for the present invention;

FIG. 7 is a perspective view illustrating a work transfer apparatus according to a fourth embodiment of the present invention;

FIG. 8 is a side view illustrating parts of the work transfer apparatus of FIG. 7;

FIG. 9 is a front view illustrating parts of the work transfer apparatus of FIG. 7;

FIG. 10 is a side view illustrating parts of a work transfer apparatus according to a fifth embodiment of the present invention;

FIG. 11 is a front view illustrating parts of the work transfer apparatus of FIG. 10; and

FIG. 12 is a perspective view illustrating a work transfer apparatus according to a sixth embodiment of the present invention.

### DETAILED DESCRIPTION OF THE PREFERRED EMBODIMENTS

Preferred embodiments of the present invention are described below with reference to the accompanying drawings.

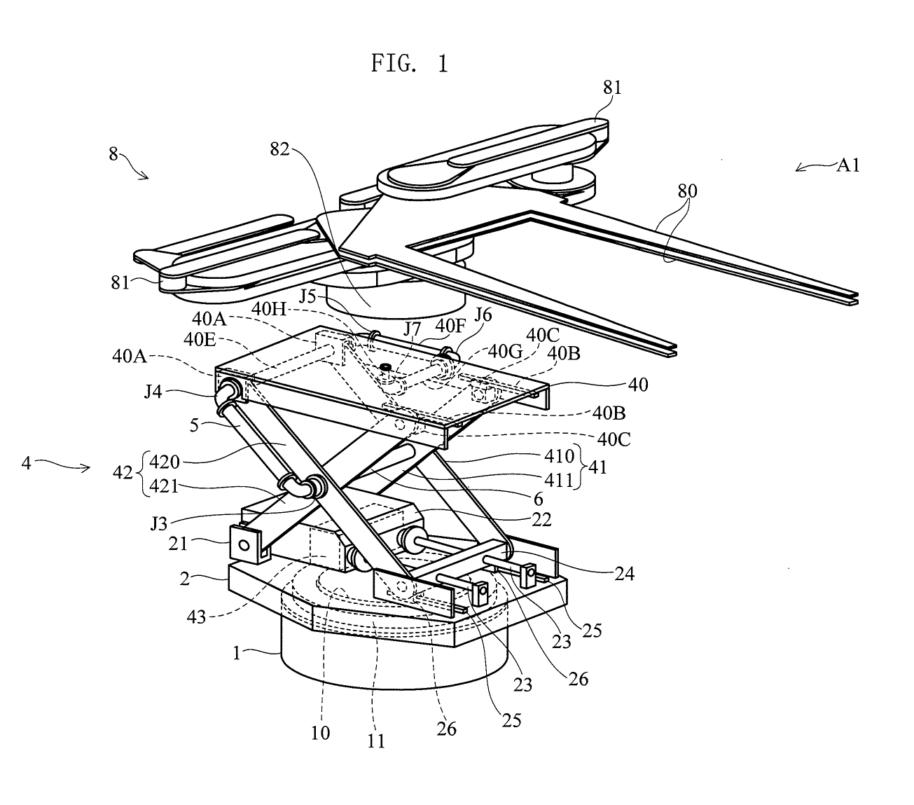

FIGS. 1-3 illustrate a work transfer apparatus according to a first embodiment of the present invention. The work transfer apparatus A1 is designed to transfer thin plate-shaped works (such as liquid crystal panels). The work transfer apparatus A1 includes a bottom unit 1, a seat 2, a scissors lift mechanism 4, an upper pipe 5, a middle pipe 6, a lower pipe 7 and a hand mechanism 8. The bottom unit 1 is arranged in an atmospheric space under a floor surface, whereas the seat 2, the scissors lift mechanism 4, the upper pipe 5, the middle pipe 6, the lower pipe 7 and the hand mechanism 8 are arranged in a vacuum space in e.g. a chamber. The work transfer apparatus A1 transfers a work heated to about 200° C. in a vacuum space. In FIG. 1, the scissors lift mechanism 4 and the hand mechanism 8 are illustrated as separated from each other for convenience of illustration. The inside of the chamber does not necessarily need to be a perfect vacuum but may be a space with a reduced pressure. Alternatively, the inside of the chamber may be a space with a predetermined increased pressure. The chamber may be filled with a gas (e.g. nitrogen) other than air.

The bottom unit 1 accommodates a rotary mechanism for rotating the seat 2 around a vertical axis. The rotary mechanism includes, for example, a rotation driving motor and a sun-and-planet gear mechanism cooperating with the driving motor. The rotary mechanism includes a rotation shaft 10 which may be hollow and connected to the bottom of the seat 2 (see FIG. 1). A seal bearing 11 is provided around the upper end of the rotation shaft 10. When the rotation shaft 10 rotates, the seat 2 rotates around a vertical axis. The inside of the bottom unit 1 is maintained at atmospheric pressure. The bottom unit 1 accommodates only the rotary mechanism for rotating the seat 2, so that the bottom unit 1 is considerably smaller in size, particularly in height, than that of the conventional work transfer apparatus. Thus, the bottom unit 1 can be placed in a narrower space (underfloor space) than is conventionally possible.

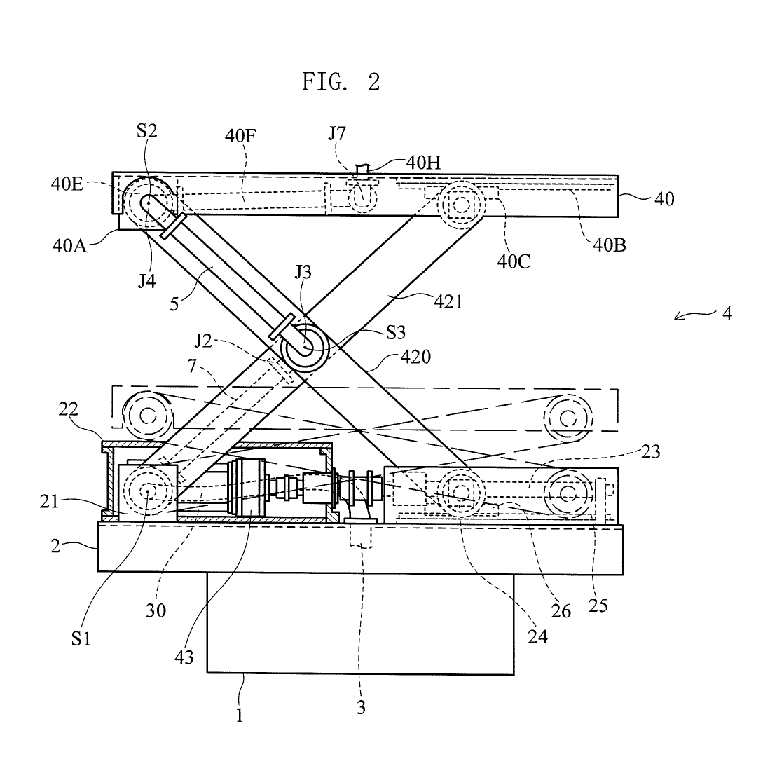

The seat 2 supports the scissors lift mechanism 4. The seat 2 is provided with a through pipe 3. The lower end of the through pipe 3 extends through the hollow portion of the rotation shaft 10 into the bottom unit 1. The upper end of the through pipe 3 is connected to the lower pipe 7 via a bottom joint pipe 30 (see FIG. 2).

The scissors lift mechanism 4 supports the hand mechanism 8 and moves the hand mechanism 8 as a whole up and down in the vertical direction. The scissors lift mechanism 4 includes a stage 40 on which the hand mechanism 8 is mounted, a first and a second scissors links 41, 42, and a lift driving motor 43. The first scissors link 41 includes a pair of cross arms 410 and 411 crossing each other at their center so as to be rotatable around a third horizontal axis S3. Likewise, the second scissors link 42 includes a pair of cross arms 420 and 421 crossing each other at their center as to be rotatable around the third horizontal axis S3. The first and the second scissors links 41 and 42 are arranged on opposite sides of the stage 40 in parallel to each other. The respective lower ends of the cross arms (first cross arms) 411 and 421, which extend in parallel to each other, are connected to the seat 2 to be rotatable around a first horizontal axis S1. The respective upper ends of the other two cross arms (second cross arms) 410 and 420 are connected to the stage 40 to be rotatable around a second horizontal axis S2. The first horizontal axis S1, the second horizontal axis S2 and the third horizontal axis S3 extend in parallel to each other. During the operation of the scissors lift mechanism 4, the second horizontal axis S2 and the third horizontal axis S3 move up and down in the vertical direction.

At the rear end of the upper surface of the seat 2, a pair of brackets 21 and bearings are provided for connecting the lower ends of the cross arms 411 and 421 to be rotatable around the first horizontal axis S1. Between the two brackets 21, a motor box 22 accommodating the lift driving motor 43 in a hermetically sealed state is provided. At the front end of the upper surface of the seat 2, a pair of ball screw shafts 23, a nut block 24, a pair of slide rails 25 and a pair of linear blocks 26 are provided, for connecting the lower ends of the cross arms 410 and 420 to be slidable back and forth in the horizontal direction. When the ball screw shafts 23 are rotated by the lift driving motor 43, the nut block 24 screwed to the ball screw shafts 23 slides back and forth. The respective lower ends of the cross arms 410 and 420 are rotatably connected to the opposite ends of the nut block 24. The lower ends of the cross arms 410, 420 are supported by the slide rails 25 via the linear blocks 26.

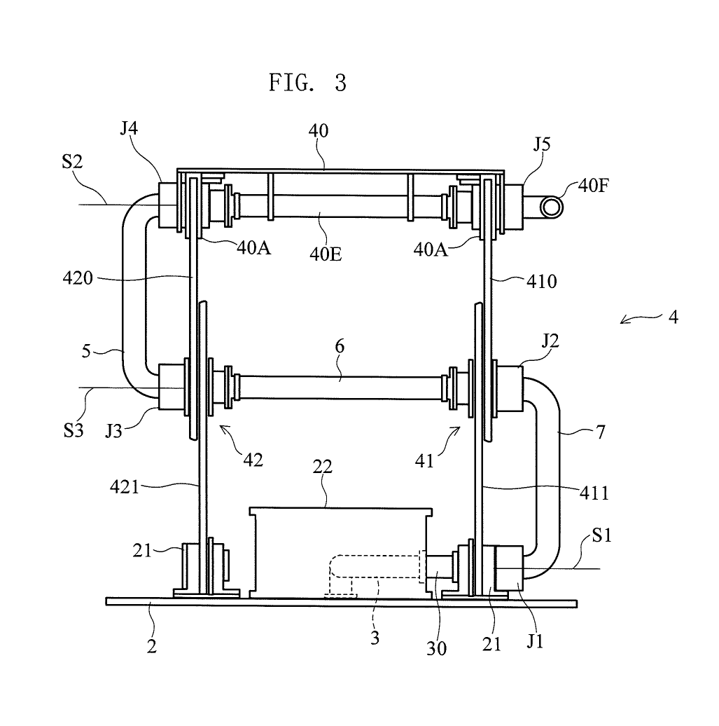

As illustrated in FIG. 3, the through pipe 3 extends into the hermetically sealed motor box 22 and is communicably connected to the bottom joint pipe 30 extending from the inside to the outside of the motor box 22. A swivel joint J1 as a first joint is provided to penetrate the lower end of the cross arm 411 and the bracket 21. The bottom joint pipe 30 is communicably connected to the lower end of the lower pipe 7 via the swivel joint J1. The swivel joint J1 is rotatable around the first horizontal axis S1. In FIG. 3, for convenience of illustration, the lower portions of the cross arms 410, 420 and the upper portions of the cross arms 411, 421 are not shown.

The upper pipe 5 is provided on the outer side of the cross arm 420 to extend from the upper end to the crossing point of the cross arm 420. The middle pipe 6 extends to bridge between the crossing point of the cross arms 410, 411 and the crossing point of the cross arms 420, 421. As illustrated in FIG. 3, the lower pipe 7 is provided on the outer side of the cross arm 411 to extend from the crossing point to the lower end of the cross arm 411. An L-shaped joint J2 as a second joint is provided to penetrate the crossing point of the cross arms 410, 411. The upper end of the lower pipe 7 is communicably connected to one end of the middle pipe 6 via the L-shaped joint J2. The other end of the middle pipe 6 is communicably connected to the lower end of the upper pipe 5 via a swivel joint J3 provided to penetrate the crossing point of the cross arms 420, 421. The swivel joint J3, a third joint, is rotatable around the third horizontal axis S3.

The hand mechanism 8 is fixed to the upper surface of the stage 40. At the rear end of the lower surface of the stage 40, a pair of brackets 40A and bearings are provided for connecting the upper ends of the cross arms 410 and 420 to be rotatable around the second horizontal axis S2. At the front end of the lower surface of the stage 40, a pair of slide rails 40B and a pair of linear guides 40C are provided for connecting the upper ends of the cross arms 411 and 421 to be slidable back and forth in the horizontal direction. Connection pipes 40E, 40F, 40G and a through connection pipe 40H are provided on the lower surface of the stage 40 in a region between the rear end and the center. One and of the connection pipe 40E is communicably connected to the upper end of the upper pipe 5 via a swivel joint J4 provided to penetrate the upper end of the cross arm 420 and the bracket 40A. The swivel joint J4, a fourth joint, is rotatable around the second horizontal axis S2. The other end of the connection pipe 40E is communicably connected to one end of the connection pipe 40F via an L-shaped joint J5 provided to penetrate the upper end of the cross arm 410 and the bracket 40A. The other end of the connection pipe 40F is communicably connected to one end of the connection pipe 40G via an L-shaped joint J6. The other end of the connection pipe 40G is communicably connected to the lower end of the through connection pipe 40H, which penetrates the center of the stage 40, via an L-shaped joint J7. The upper end of the through connection pipe 40H is connected to an appropriate portion (e.g. to an upper box 82 to be described later) of the hand mechanism 8.

The through pipe 3, the bottom joint pipe 30, the upper pipe 5, the middle pipe 6, the lower pipe 7, the connection pipes 40E, 40F, 40G and the through connection pipe 40H constitute a continuous conduit extending from the inside of the bottom unit 1 to the hand mechanism 8. The conduit is hermetically sealed to maintain atmospheric pressure in the conduit. In the conduit are provided power cables for supplying electric power to a slide driving motor of the hand mechanism 8, which will be described later, and to the lift driving motor 43. The conduit further accommodates a refrigerant circulation pipe for cooling appropriate portions of the hand mechanism 8. With this arrangement, the power cables and the refrigerant circulation pipe are laid to extend from within the bottom unit 1 to the motor box 22 or the hand mechanism 8, without being exposed to the vacuum space. The refrigerant may be a gas such as dry air or a liquid such as water. In the illustrated example, the conduit between the upper pipe 5 and the hand mechanism 8 is made up of the connection pipes 40E, 40F, 40G and the through connection pipe 40H, though the present invention is not limited to this. Since the positional relationship between the upper end of the upper pipe 5 and the hand mechanism 8 does not change even when the scissors lift mechanism 4 moves, the upper end of the upper pipe 5 and the hand mechanism 8 may be connected via a pipe, for example.

The hand mechanism 8 includes two hands 80 for holding a work, two slide link mechanism 81 for individually moving the two hands 80 straight back and forth in the horizontal direction, slide driving motors for driving the slide link mechanisms 81, and the hermetically sealed upper box 82 accommodating the slide driving motors. Two slide driving motors may be provided in the upper box 82 for individually driving the two slide link mechanism 81. The upper box 82 is fixed to the center of the upper surface of the stage 40. The through connection pipe 40H is hermetically connected to the bottom of the upper box 82. In the upper box 82 and around the slide link mechanisms 81, a refrigerant circulation path is provided, which is connected to the refrigerant circulation pipe extending from the through connection pipe 90H. With such a refrigerant circulation path provided, the interior of the slide link mechanisms 81 and the upper box 82, heated by the radiant heat from a high-temperature work during the transferring operation, are efficiently cooled. As a result, deformation by thermal expansion and deterioration of transfer accuracy can be prevented.

The workings of the work transfer apparatus A1 will be described below.

In transferring a work in a vacuum space, the hand mechanism 8 holding the work is operated to move in the horizontal direction, and the scissors lift mechanism 9 is operated to move the hand mechanism 8 up and down in the vertical direction. The rotary mechanism accommodated in the bottom unit 1 collectively rotates the hand mechanism 8 and the scissors lift mechanism 4. By these operations, the work is transferred from a predetermined position to a desired position in the three dimensional space.

As illustrated in FIG. 2, to operate the scissors lift mechanism 4, the ball screw shafts 23 are rotated so that the nut block 24 slides back and forth in the horizontal direction along the ball screw shafts 23. Since the lower ends of the cross arms 410 and 420 are connected to the opposite ends of the nut block 24, the lower ends of the cross arms 410 and 420 slide along the slide rails 25.

In accordance with the sliding movement of the lower ends of the cross arms 410 and 420, the upper ends of the cross arms 410 and 420 rotate around the second horizontal axis S2. The lower ends of the other two cross arms 411 and 421 rotate around the first horizontal axis S1, so that the upper ends of the cross arms 411 and 421 slide along the slide rails 40B. As a result, the stage 40 moves up and down in the vertical direction while keeping the horizontal posture.

Referring to FIG. 2, when the stage 40 is moved down vertically to the position indicated by phantom lines as the scissors lift mechanism 4 operates, the hand mechanism 8 mounted on the stage 40 is brought to the position lowest with reference to the seat 2.

Due to the above-noted structure of the scissors lift mechanism 4, there is a gap in the height direction between the seat 2 and the stage 40, even when the stage 40 is moved to the lowest position by the scissors lift mechanism 4. The motor box 22 is arranged in the gap, so that the space on the seat 2 is put to efficient use.

The height of the motor box 22 depends on the size of the lift driving motor 43, for example. It is possible that the motor box 22 cannot be properly accommodated in the gap present when the stage 40 is at the lowest position. In such an instance, if the stage 40 is moved to the lowest position by the scissors lift mechanism 4, the motor box 22 may come into undesired contact with the stage 40 or the connection pipes 40E, 40G. To prevent this, the movement of the scissors lift mechanism 4 in the height direction may be limited so that the contact between the motor box 22 and the stage 40 or the connection pipes 40E, 40G does not occur. Alternatively, an additional, contact prevention means may be used, or the motor box 22 may be disposed at a position that can avoid the contact with the stage 40 or the connection pipes 40E, 40G. In the latter case, the seat 2 (the area of its upper surface) may need to be increased in size. The use of an intervening gear box provided between the lift driving motor 43 and the ball screw shafts 23 may allow greater flexibility in deciding the installation position of the motor box 22.

When the scissors lift mechanism 4 operates, the positional relationship between the upper pipe 5, the middle pipe 6, the lower pipe 7 and the connection pipe 40E changes. Since the upper pipe 5, the middle pipe 6, the lower pipe 7 and the connection pipe 40E are communicably and rotatably connected to each other via the hermetically sealed swivel joints J1, J3, J4 and L-shaped joint J2, the inner power cables and the refrigerant circulation pipe do not become disordered. Thus, even when the rotary mechanism operates, the power cable and the refrigerant circulation pipe do not get tangled or unduly bent.

In the work transfer apparatus A1, the work transferring mechanism is provided by the hand mechanism 8, the scissors lift mechanism 4 and the rotary mechanism, among which only the rotary mechanism is arranged under the seat 2. Thus, the bottom unit 1 for accommodating the rotary mechanism can be small in height, and hence the work transfer apparatus A1 as a whole can be compact.

The power cable and the refrigerant circulation pipe are guided from the bottom unit 1 to the hand mechanism 8 in a conduit-accommodated condition. Thus, the power cable and the refrigerant circulation pipe do not hinder the operation of the scissors lift mechanism 4 or the rotary mechanism.

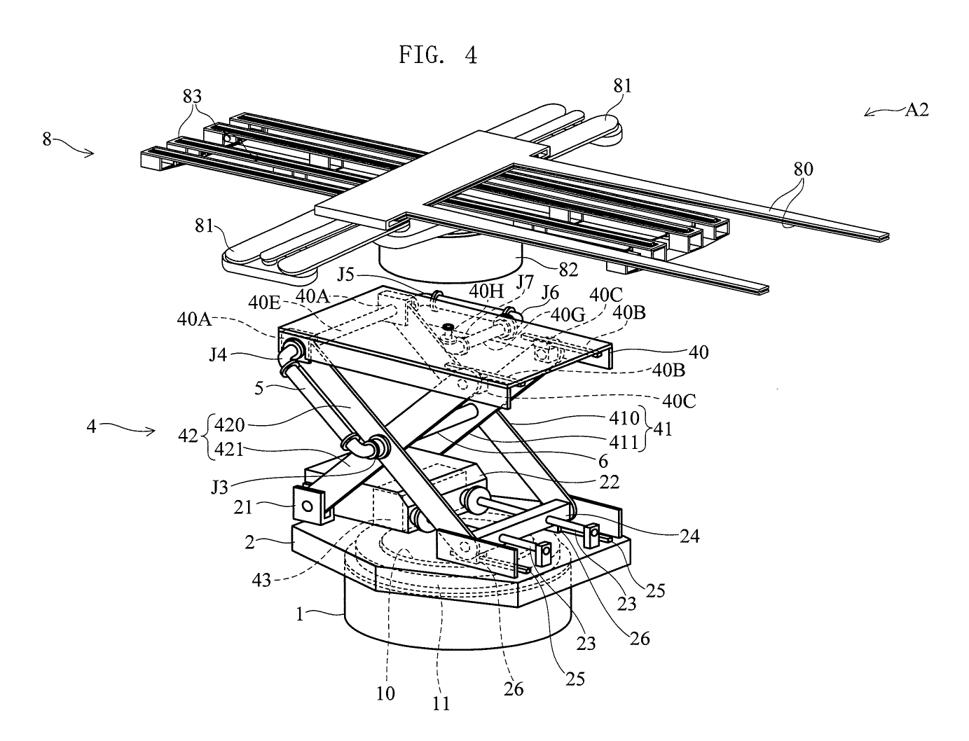

FIGS. 4-12 illustrate work transfer apparatuses according to second through sixth embodiments of the present invention. In these figures, elements identical or similar to those of the foregoing first embodiment are designated by the same reference signs, and the workings of these elements may not be explained below.

FIG. 4 illustrates a work transfer apparatus A2 according to the second embodiment of the present invention. The work transfer apparatus A2 differs from the apparatus A1 of the first embodiment in the hand mechanism 8. Specifically, the hand mechanism 8 of the apparatus A2 includes guide rails 83 for enabling the hands 80 to slide while keeping the horizontal posture. The upper box 82 is arranged below the guide rails 83. A refrigerant circulation path, though not shown, is arranged in the upper box 82 and a round the guide rails 83. The refrigerant circulation path is connected to the refrigerant circulation pipe extending from the through connection pipe 40H.

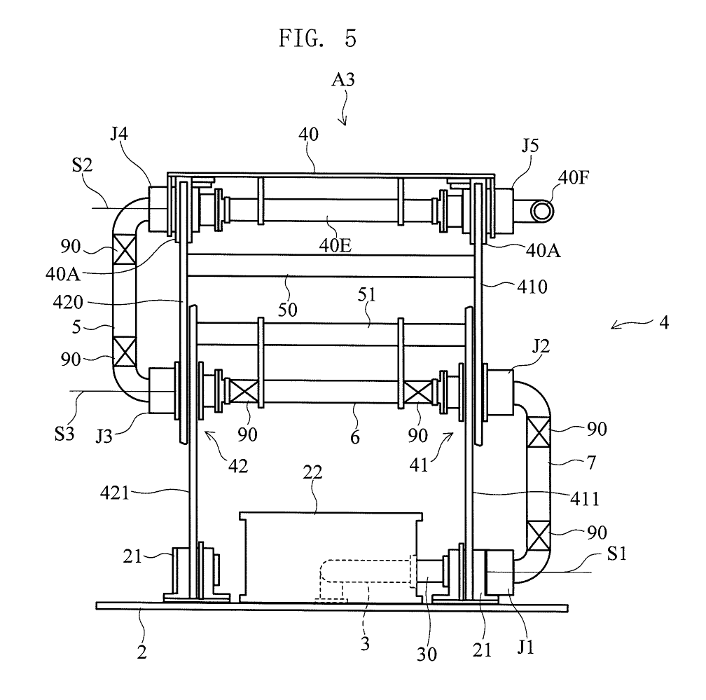

FIG. 5 illustrates a work transfer apparatus A3 according to the third embodiment of the present invention. In the work transfer apparatus A3, a reinforcing shaft 50 is provided slightly below the upper ends of the cross arms 410, 420 to bridge between these arms. Further, another reinforcing shaft 51 is provided slightly above the crossing points of the cross arms 411 and 421, so as to bridge between these arms and support the middle pipe 6. The reinforcing shafts 50, 51 enhance the mechanical strength of the scissors lift mechanism 4.

In the scissors lift mechanism 4, a temperature difference may arise between the upper portion and the lower portion, which may lead to thermal deformation of the cross arms 410, 411, 420, 421. To prevent this, as shown in FIG. 5, the upper pipe 5, the middle pipe 6 and the lower pipe 7 may be partially provided with elastic portions 90. The elastic portions 90 may be in the form of a bellows so as to be capable of freely expanding and contracting while keeping the air tightness. With such an arrangement, the scissors lift mechanism 4 can operate properly, even when the first and second scissors links 41, 42 are thermally deformed within tolerable limits.

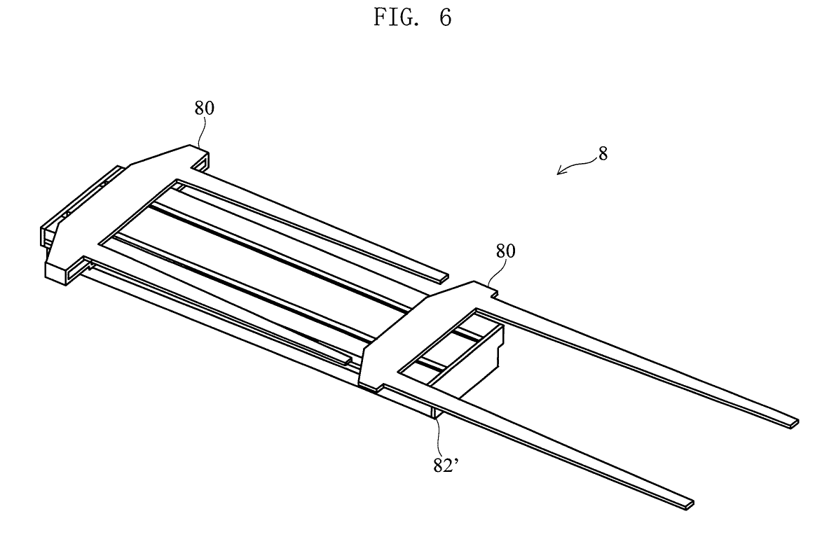

The hand mechanism to be mounted on the scissors lift mechanism may have a structure as illustrated in FIG. 6. Specifically, the illustrated hand mechanism includes a guide member 82′ which incorporates a belt driving mechanism (not shown) for individually operating the two hands 80, and each of the hands 80 slides on the guide member 82′ back and forth in the horizontal direction. The guide member 82′ is internally provided with the belt driving mechanism and the hermetically sealed case in which the slide driving motor is accommodated. A refrigerant circulation path may be provided in or around the guide member 82′. In this instance, a through connection pipe (40H) may be hermetically connected to the case in the guide member 82′. With this arrangement, the refrigerant circulation pipe and the power cable for the slide driving motor can be guided into the case of the guide member 82′ through the through connection pipe.

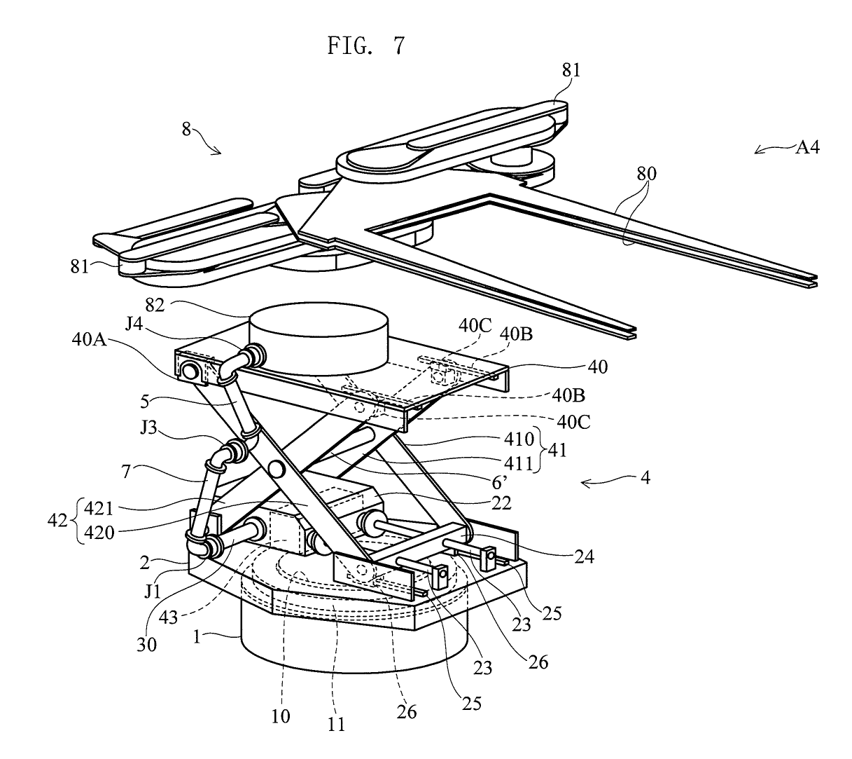

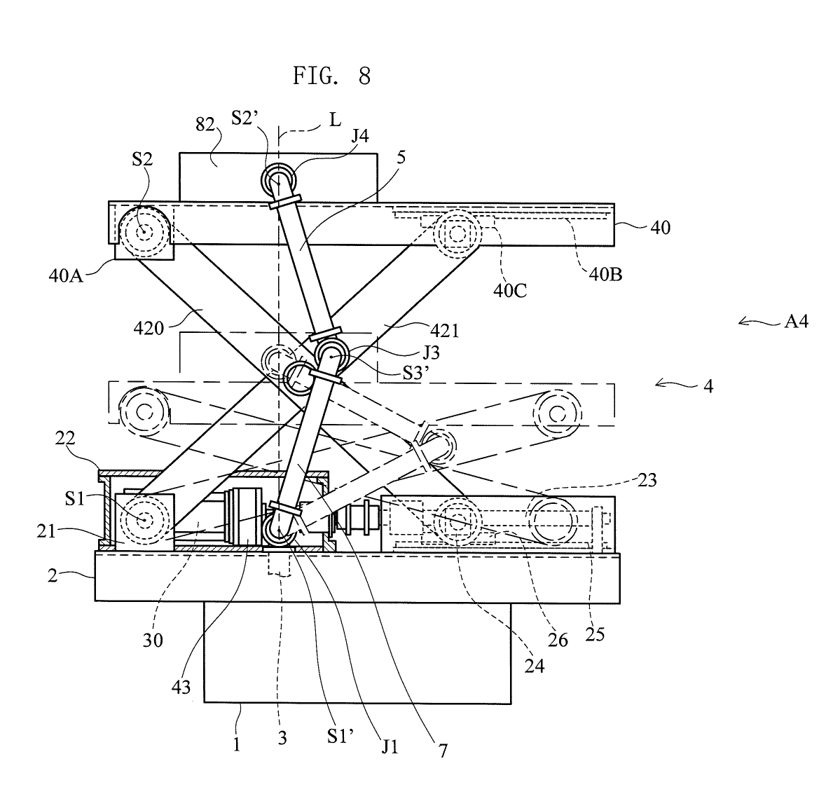

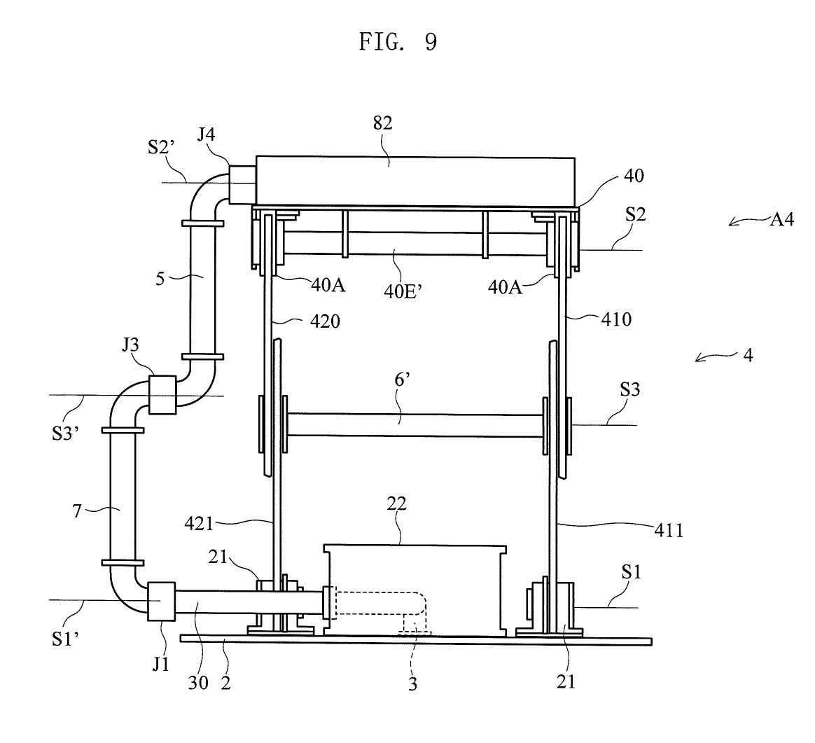

FIGS. 7-9 illustrate a work transfer apparatus A4 according to the fourth embodiment of the present invention. The work transfer apparatus A4 differs from that of the foregoing first embodiment in arrangement of pipes. Specifically, the work apparatus A4 includes, as pipes, a through pipe 3 (illustrated in FIGS. 8 and 9), a bottom joint pipe 30, an upper pipe 5 and a lower pipe 7. The upper pipe 5 and the lower pipe 7 are provided to connect the bottom unit 1 and the upper box 82 to each other, while detouring around the scissors lift mechanism 4. As illustrated in FIGS. 7 and 9, a middle pipe 6′ and an upper rotation shaft 40E′ are provided to bridge between the first and the second scissors links 41 and 42, similarly to the above-described middle pipe 6 and connection pipe 40E. However, the middle pipe 6′ and the upper rotation shaft 40E′ do not function as a conducting pipe but as a reinforcing shaft to increase the mechanical strength of the scissors lift mechanism 4, thereby allowing smooth operation. Other structural elements are the same as those of the work transfer apparatus A1. For example, the operation of the scissors lift mechanism 4 itself is the same as that of the work transfer apparatus A1.

As illustrated in FIG. 8, the through pipe 3 penetrates the seat 2 to connect between the bottom unit 1 and the motor box 22. As illustrated in FIG. 9, the through pipe 3 is communicably connected to the bottom joint pipe 30 projecting horizontally from within the motor box 22. As illustrated in FIG. 7, the bottom joint pipe 30 extends outwards through a lower space between the cross arms 420 and 421 of the second scissors link 42. With this arrangement, the scissors lift mechanism 4 can be lowered to a position which is slightly higher than where the cross arms 420 and 421 come into contact with the bottom joint pipe 30 (see phantom lines in FIG. 8).

The upper pipe 5 is arranged on the outer side of the scissors lift mechanism 4, and its upper end is communicably connected to the upper pox 82 on the stage 40 via a swivel joint J4. The upper end of the upper pipe 5 is rotatable around a second horizontal axis S2′ due to the swivel joint J4. The lower end of the upper pipe 5 is communicably connected to the upper end of the lower pipe 7 via a swivel joint J3 arranged on the outer side of the scissors lift mechanism 4. The lower end of the upper pipe 5 is also rotatable around a third horizontal S3′ by the swivel joint J3.

The lower pipe 7 is arranged on the outer side of the scissors lift mechanism 4 so as to be at a position farther from the scissors lift mechanism 4 than the upper pipe 5 is. The lower end of the lower pipe 7 is communicably connected to the bottom joint pipe 30 via a swivel joint J1. The lower end of the lower pipe 7 is rotatable around a first horizontal axis S1′ due to the swivel joint J1. The upper end of the lower pipe 7 is connected to the lower end of the upper pipe 5 via the swivel joint J3. Thus, the upper pipe 5 and the lower pipe 7 are rotatable relative to each other around the third horizontal axis S3′ due to the swivel joint J3 disposed at the communicable connection point of the two pipes. The first horizontal axis S1′, the second horizontal axis S2′ and the third horizontal axis S3′ extend in parallel to each other. During the operation of the scissors lift mechanism 4, the first horizontal axis S1′ does not move relative to the seat 2, whereas the second horizontal axis S2′ and the third horizontal axis S3′ move up and down in the vertical direction.

When the scissors lift mechanism 4 is viewed in the direction normal to FIG. 8, the first horizontal axis S1′ and the second horizontal axis S2′ are constantly positioned on a vertical axis L. The distance between the first horizontal axis S1′ and the third horizontal axis S3′ along the lower pipe 7 is equal to the distance between the second horizontal axis S2′ and the third horizontal axis S3′ along the upper pipe 5. When the scissors lift mechanism 4 is at the highest position, the distance between the first horizontal axis S1′ and the second horizontal axis S2′ along the vertical line L is shorter than the total of the above two inter-axial distances. Accordingly, the third horizontal axis S3′ is constantly positioned on the same side of the vertical line L, and the upper pipe 5 and the lower pipe 7 are connected to each other in a manner bending at the connection point where the third horizontal axis S3′ is present.

With the above-described geometric relationship, when the scissors lift mechanism 4 is operated to move from the highest position to the lowest position, the third horizontal axis S3′ is moved only on the same side of the vertical line L and never passes through the dead point on the vertical line L. In accordance with the up-and-down movement of the scissors lift mechanism 4, the upper pipe 5 and the lower pipe 7 smoothly rotate in mutually opposite directions around the third horizontal axis S3′. Also, when the scissors lift mechanism 4 moves to the highest position or the lowest position, the third horizontal axis S3′ does not move upwards beyond the stage 90 or downwards beyond the seat 2. Likewise, the upper pipe 5 and the lower pipe 7 do not extend above the stage 40 or below the seat 2. Thus, as the scissors lift mechanism 4 performs up- or down-movement, the upper pipe 5 and the lower pipe 7 can rotate properly within as small a range of motion as possible.

The through pipe 3, the bottom joint pipe 30, the upper pipe 5 and the lower pipe 7 constitute a continuous conduit extending from the inside of the bottom unit 1 to the upper box 82 of the hand mechanism 8. The conduit is hermetically sealed to maintain atmospheric pressure in the conduit. Similarly to the foregoing embodiment, the conduit accommodates a power cable for supplying electric power to the slide driving motor of the hand mechanism 8 and a refrigerant circulation pipe for cooling appropriate portions of the hand mechanism 8.

In the work transfer apparatus A9, when the scissors lift mechanism 4 moves up and down in the vertical direction, the upper pipe 5 and the lower pipe 7 rotate in accordance with the up-and-down movement of the stage 40. The upper pipe 5 and the lower pipe 7 are communicably and rotatably connected to each other via the hermetically sealed swivel joint J3. Thus, the power cable and the refrigerant circulation pipe arranged in the pipes do not bend or twist unduly.

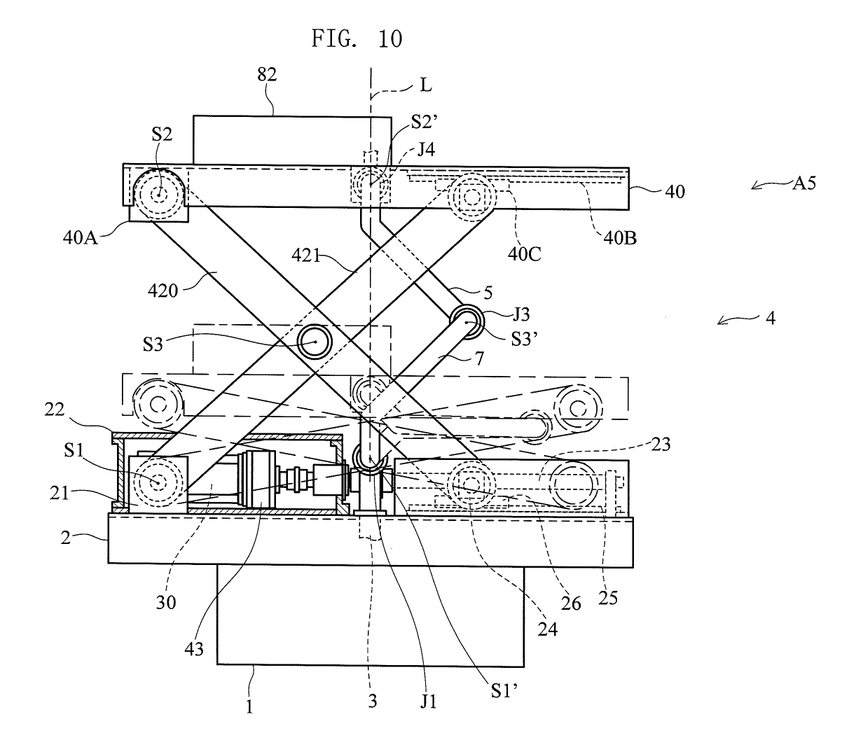

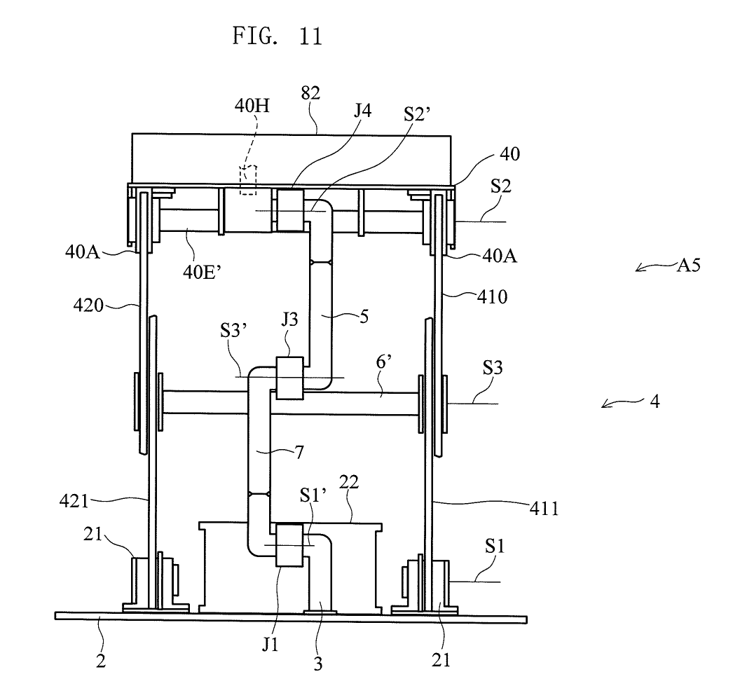

FIGS. 10 and 11 illustrate a work transfer apparatus A5 according to the fifth embodiment of the present invention. The work transfer apparatus A5 also includes a through pipe 3, an upper pipe 5, and a lower pipe 7 to constitute a conduit, but differs from the foregoing work transfer apparatus A4 in shape and arrangement of these pipes. Specifically, in the work transfer apparatus A5, the through pipe 3, the upper pipe 5 and the lower pipe 7 are arranged between the first and the second scissors links 41 and 42. A through connection pipe 40H, which penetrates the stage 40, is connected to a lower portion of the upper box 82. The upper end of the upper pipe 5 is connected to the through connection pipe 90H via a swivel joint J4. Thus, the upper end of the upper pipe 5 is rotatable around a second horizontal axis S2′.

As illustrated in FIG. 10, the through pipe 3 penetrates through the center of the seat 2 and extends between a pair of ball screw shafts 23 provided outside the motor box 22. The upper end of the through pipe 3 extends horizontally, to which the lower end of the lower pipe 7 is connected via a swivel joint J1. Thus, the lower end of the lower pipe 7 is rotatable around a first horizontal axis S1′.

As illustrated in FIG. 11, the upper pipe 5 and the lower pipe 7, arranged between the first and the second scissors links 41 and 42, are rotatable in the space between the stage 40 and the seat 2. As illustrated in FIG. 10, the upper pipe 5 and the lower pipe 7 as a whole have a bent portion and are communicably connected to each other via a middle swivel joint J3. The upper pipe 5 and the lower pipe 7 as a whole are bent away from the vertical line L connecting the first horizontal axis S1′ and the second horizontal axis 52′, in other words, bent forward in a direction in which the first and the second scissors links 41 and 42 are caused to slide. Accordingly, when the scissors lift mechanism 4 moves up and down, the third horizontal axis S3′ is on the same side of the vertical line L, and even when the scissors lift mechanism 4 descends to the lowest position, the upper pipe 5 and the lower pipe 7 are folded between the stage 40 and the seat 2, avoiding undesired contact with the nut block 24, for example. With such an arrangement, the scissors lift mechanism 4 can descend to the lowest position, while the stage 40 does not come into contact with the motor box (see phantom lines in FIG. 10).

With the above-noted arrangement and shape of the upper pipe 5 and the lower pipe 7, when the scissors lift mechanism 4 moves vertically between the highest position and the lowest position, the upper pipe 5 and the lower pipe 7 rotate smoothly in the opposite directions around the swivel joint J3 between the stage 40 and the seat 2. In this process, the swivel joint J3 and the upper and lower pipes 5 and 7, which are rotatable around the third horizontal axis S3′, can move within the smallest range possible without hindrance, without coming into contact with the other members on the seat 2.

The through pipe 3, the upper pipe 5, the lower pipe and the through connection pipe 40H constitute a continuous conduit extending from the inside of the bottom unit 1 to the upper box 82 of the hand mechanism 8. The conduit is hermetically sealed to maintain atmospheric pressure in the conduit. Similarly to the foregoing embodiments, the conduit accommodates a power cable for supplying electric power to the slide driving motor of the hand mechanism 8 and also a refrigerant circulation pipe for cooling appropriate portions of the hand mechanism 8.

In the work transfer apparatus A5, when the scissors lift mechanism 4 moves up and down in the vertical direction, the upper pipe 5 and the lower pipe 7 rotate in accordance with the up-and-down movement of the stage 40. The upper pipe 5 and the lower pipe 7 are communicably connected to each other via the hermetically sealed swivel joint J3 to be rotatable around the third horizontal axis S3′. Thus, the accommodated power cable and refrigerant circulation pipe do not unduly bend or twist.

According to the work transfer apparatus A5 described above, it is possible to arrange the power cable and the refrigerant circulation pipe properly, and also to make compact the apparatus as a whole by arranging pipes in the space between the stage 40 and the seat 2.

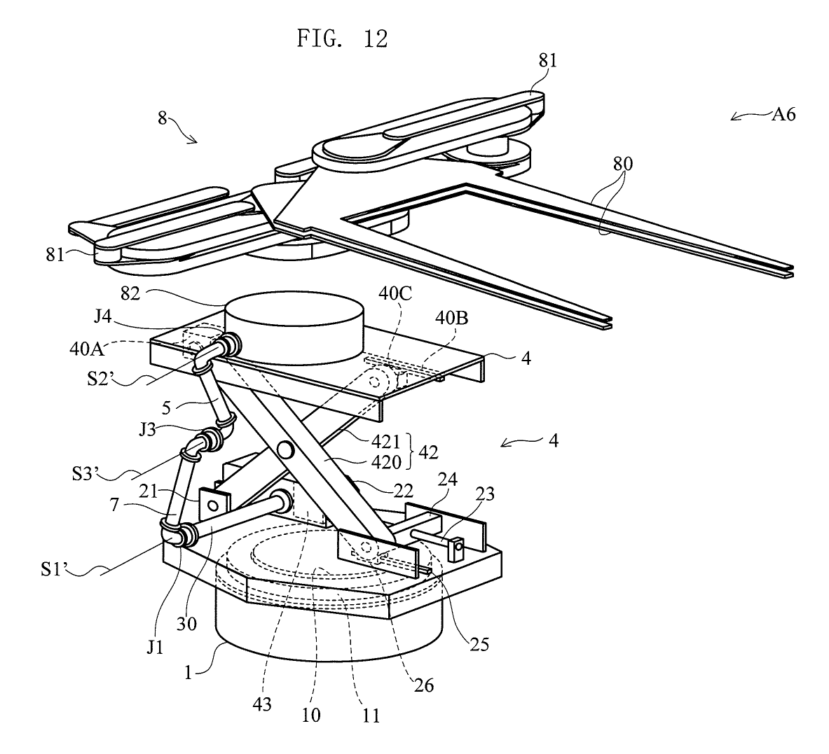

FIG. 12 illustrates a work transfer apparatus A6 according to the six embodiment of the present invention. The work transfer apparatus A6 differs from the work transfer apparatus A4 of FIGS. 7-9 in the structure of the scissors lift mechanism 4. The scissors lift mechanism 4 of the work transfer apparatus A6 is configured to move the stage 40 up and down by only a single scissors link 42. The scissors link 42 is made up of two cross arms 420 and 421 which are elongated, and relatively thick so that the scissors link 42 alone can support the weight of the stage 40 and the hand mechanism 8 mounted on the stage. The operation of the scissors lift mechanism 4 is the same as that of the work transfer apparatus A1. The through pipe, the bottom joint pipe 30, the upper pipe 5 and the lower pipe 7 are connected in the same manner as those of the work transfer apparatus A4.

The present invention is not limited to the foregoing embodiments.

In the foregoing embodiments, swivel joints are used for elements J1, J3, J4 and non-rotatable L-shaped joints are used for elements J2, J5. The present invention, however, is not limited to this. For instance, in the work transfer apparatus A1 of FIG. 1, the elements J1, J2, J5 may be swivel joints, and the elements J3, J4 may be L-shaped joints. Other arrangements using swivel joints may be adopted as long as the middle pipe 6 and the connection pipe 40E are allowed to rotate when the scissors lift mechanism 4 operates. If the elements J2-J5 were all L-shaped joints, no rotational movement would be allowed at the both ends of the middle pipe 6 and the connection pipe 40E, and hence the scissors lift mechanism 4 could not operate. Thus, in the scissors lift mechanism 4, a swivel joint is to be provided at one end of each of the middle pipe 6 and the connection pipe 40E, in addition to the swivel joint J1, so that the scissors lift mechanism 4 can unrestrictedly move up and down. It is possible, of course, that all the elements J1-J5 may be swivel joints.

In the work transfer apparatus A6 of FIG. 12, use may be made of the pipes as illustrated in FIGS. 10 and 11. With such an arrangement, the work transfer apparatus as a whole can be reduced in weight and in size.

The work transfer apparatuses A4-A6 illustrated in FIGS. 7-12 can also employ the hand mechanism 8 as illustrated in FIG. 1, 4 or 6.

The cross arms 410 and 411 of the first scissors link 41 or the cross arms 420 and 421 of the second scissors link 42 cross each other at the middle of their length. Alternatively, two cross arms may be arranged to cross each other at a position longitudinally offset from the middle toward the upper or lower end of the respective arms.

In the work transfer apparatuses A4-A6 of FIGS. 7-12, it is possible, as long as the upper pipe 5 and the lower pipe 7 can move properly without coming into contact with other members, that the distance between the axes along the upper pipe 5 and the lower pipe 7 may be different from each other or that the straight line connecting the first horizontal axis S1′ and the second horizontal axis S2′ may be inclined relative to the vertical line L.

As a variation of the work transfer apparatuses A4-A6 of FIGS. 7-12, a middle pipe, rotatable about a horizontal axis, may be additionally used to communicably connect between the upper pipe 5 and the lower pipe 7. In this instance, when the stage 40 moves up and down, these three pipes are moved in a foldable manner.

The straight line connecting the first horizontal axis S1′ and the second horizontal axis S2′ may be inclined relative to the vertical line L. In such an instance, the third horizontal axis S3′ illustrated in FIGS. 8, 10 and 12 is to be positioned on the same side of the inclined line.

The positions of the first horizontal axis S1′ and the second horizontal axis S2′ are not limited to those illustrated in FIGS. 8, 10 and 12. For instance, the first horizontal axis S1′ and the second horizontal axis S2′ may be disposed at the same positions as the first horizontal axis S1 and the second horizontal axis S2 illustrated in FIG. 2.

The upper and the lower ends of each of the upper pipe 5 and the lower pipe 7 may be structured similarly to a swivel joint. In this instance, the lower end of the upper pipe 5 and the upper end of the lower pipe 7 can be connected directly, i.e., without using a swivel joint, to the opposite ends of the middle pipe 6 in a rotatable manner around the third horizontal axis S3.

The work transfer apparatuses A1-A6 of the present invention are also applicable to conditions under which no cooling function is required. In this case, it is not necessary to arrange a refrigerant circulation pipe in the conduit.

1. A work transfer apparatus comprising:
a hand mechanism for reciprocally moving a work;
a scissors lift mechanism for supporting the hand mechanism and moving the hand mechanism up and down in a vertical direction;
a seat supporting the scissors lift mechanism; and
a rotary mechanism for rotating the seat around a vertical axis.

2. The work transfer apparatus according to claim 1, wherein:
the hand mechanism includes a hand for holding the work, a slide link mechanism supporting the hand and linearly moving the hand reciprocally, and a slide driver for operating the slide link mechanism;
the scissors lift mechanism includes a stage supporting the hand mechanism, at least one scissors link, and a lift driver;
the scissors link includes a first and a second cross arms rotatably connected to each other at a crossing point, the first cross arm including an upper end that is slidable relative to the stage in a horizontal direction, the first cross arm including a lower end connected to the seat rotatably around a first horizontal axis, the second cross arm including an upper end that is rotatable relative to the stage around a second horizontal axis, the second cross arm including a lower end connected to the seat slidably in a horizontal direction; and
the lift driver is mounted on the seat and configured to cause the lower end of the second cross arm to slide relative to the seat.

3. The work transfer apparatus according to claim 2, further comprising a plurality of pipes arranged between the hand mechanism and the seat, wherein the pipes are communicably connected to each other and rotatable around a horizontal axis.

4. The work transfer apparatus according to claim 3, further comprising a cable accommodated in the pipes and connected to the hand mechanism.

5. The work transfer apparatus according to claim 3, wherein:
the scissors link includes a first and a second scissors links provided on the seat in parallel to each other;
the pipes include a lower pipe, an upper pipe, and a middle pipe arranged between the upper pipe and the lower pipe, the upper pipe and the lower pipe being spaced from each other in a horizontal direction; and
the lower pipe extends from the lower end of the second cross arm of the first scissors link to the crossing point in the first scissors link, the upper pipe extends from the upper end of the second cross arm of the second scissors link to the crossing point in the second scissors link, and the middle pipe is disposed between the crossing points in the first scissors link and the second scissors link and communicably connected to the lower pipe and the upper pipe.

6. The work transfer apparatus according to claim 5, further comprising a swivel joint rotatable around a third horizontal axis, wherein the swivel joint is connected to one of the lower pipe and the upper pipe and to the middle pipe.

7. The work transfer apparatus according to claim 6, further comprising a through pipe provided at the seat, wherein the through pipe is arranged to communicate with the lower pipe via the lower end of the first cross arm of the first scissors link.

8. The work transfer apparatus according to claim 7, further comprising first, second, third and fourth joints, wherein:
the first joint and the second joint are provided at the lower end and the crossing point, respectively, of the first cross arm of the first scissors link, and the third joint and the fourth joint are provided at the crossing point and the upper end, respectively, of the second cross arm of the second scissors link;
the lower end of the lower pipe is communicably connected to the through pipe directly or indirectly via the first joint, and the upper end of the lower pipe is communicably connected to the middle pipe via the second joint; and
the lower end of the upper pipe is communicably connected to the middle pipe via the third joint, and the upper end of the upper pipe is communicably connected to the hand mechanism directly or indirectly via the fourth joint.

9. The work transfer apparatus according to claim 8, wherein at least one of the second joint and the third joint is a swivel joint rotatable around the third horizontal axis.

10. The work transfer apparatus according to claim 5, further comprising a through pipe provided at the seat, wherein:
the lower end of the lower pipe is communicably connected to the through pipe directly or indirectly via the lower end of the first cross arm of the first scissors link to be rotatable around the first horizontal axis, and the upper end of the lower pipe is communicably connected to the middle pipe via the crossing point of the first cross arm of the first scissors link to be rotatable around a third horizontal axis; and
the lower end of the upper pipe is communicably connected to the middle pipe via the crossing point of the second cross arm of the second scissors link to be rotatable around the third horizontal axis, and the upper end of the upper pipe is communicably connected to the hand mechanism directly or indirectly via the upper end of the second cross arm of the second scissors link to be rotatable around the second horizontal axis.

11. The work transfer apparatus according to claim 10, further comprising a cable connected to the hand mechanism and a cable connected to the lift driver, wherein these cables are accommodated in the through pipe.

12. The work transfer apparatus according to claim 5, wherein the lower pipe, the middle pipe and the upper pipe are hermetically sealed.

13. The work transfer apparatus according to claim 5, wherein each of the lower pipe, the middle pipe and the upper pipe includes a portion using an elastic member.

14. The work transfer apparatus according to claim 3, wherein:
the pipes include an upper pipe and a lower pipe; and
the lower pipe is connected directly or indirectly to the seat to be rotatable around the first horizontal axis, the upper pipe is connected directly or indirectly to the hand mechanism to be rotatable around the second horizontal axis, and the upper pipe and the lower pipe are communicably connected to each other directly or indirectly to be rotatable around a third horizontal axis.

15. The work transfer apparatus according to claim 14, further comprising: a swivel joint rotatable around the first horizontal axis and provided at a connection portion of the lower pipe with respect to the seat; a swivel joint rotatable around the second horizontal axis and provided at a connection portion of the upper pipe with respect to the hand mechanism; and a swivel joint rotatable around the third horizontal axis and provided at a communicable connection portion between the lower pipe and the upper pipe.

16. The work transfer apparatus according to claim 15, wherein the first horizontal axis, the second horizontal axis and the third horizontal axis extend in parallel to each other, and the third horizontal axis is constantly positioned on a same side of a straight line connecting the first horizontal axis and the second horizontal axis to each other when viewed in a direction in which the first, the second and the third horizontal axes extend.

17. The work transfer apparatus according to claim 16, wherein a distance between the first horizontal axis and the third horizontal axis is equal to a distance between the second horizontal axis and the third horizontal axis, and the first horizontal axis and the second horizontal axis are spaced vertically from each other.

18. The work transfer apparatus according to claim 17, wherein the upper pipe and the lower pipe are arranged to provide a bending form.

19. The work transfer apparatus according to claim 14, further comprising a through pipe provided at the seat, wherein the lower pipe is communicably connected to the through pipe directly or indirectly to be rotatable around the first horizontal axis.

20. The work transfer apparatus according to claim 19, further comprising a cable accommodated in the through pipe and connected to the hand mechanism.
